(19) United States
(12) Patent Application Publication
(10) Pub. No.: US 2023/0048193 A1
(43) Pub. Date: Feb. 16, 2023

(54) SEMICONDUCTOR STRUCTURE AND METHOD OF FABRICATING SAME

(71) Applicant: Changxin Memory Technologies, Inc., Hefei (CN)

(72) Inventors: Ming CHENG, HEFEI (CN); Ran LI, HEFEI (CN); Zhengqing SUN, HEFEI (CN); Xing JIN, HEFEI (CN)

(21) Appl. No.: 17/851,383

(22) Filed: Jun. 28, 2022

Related U.S. Application Data
(63) Continuation of application No. PCT/CN2021/117233, filed on Sep. 8, 2021.

(30) Foreign Application Priority Data
Aug. 11, 2021 (CN) 202110919736.9

(51) Int. Cl. H01L 27/108

(52) U.S. Cl. CPC H01L 27/10814; H01L 27/10823; H01L 27/10855; H01L 27/10876

(57) ABSTRACT

The invention provides a semiconductor structure and a fabrication method for same. The semiconductor structure comprises: a substrate; a plurality of word-line structures extending along a first direction on the substrate and arranged at intervals along a second direction, wherein the second direction is perpendicular to the first direction; a plurality of spacer structures disposed above the plurality of word-line structures, wherein at least one of the plurality of spacer structures comprises a first spacer layer and an air gap, the first spacer layer is disposed at a bottom portion of the spacer structures, the air gap is disposed on the first spacer layer, and the air gap is located between the plurality of first spacer layers along the second direction; and a plurality of contact plugs disposed between the plurality of spacer structures.

### CROSS REFERENCE TO RELATED APPLICATIONS

This application is a continuation application of International Patent Application No. PCT/CN2021/117233 filed Sep. 8, 2021, which claims priority of Chinese Patent Application No. 202110919736.9 filed with the China National Intellectual Property Administration on Aug. 11, 2021 and entitled “SEMICONDUCTOR STRUCTURE AND METHOD OF FABRICATING SAME.” The above-referenced applications are incorporated herein by reference in their entirety.

### TECHNICAL FIELD

The invention relates to the field of semiconductor technology, and more particularly, to a semiconductor structure for memory and a fabrication method for same.

### BACKGROUND

As semiconductor integrated-circuit devices continue to shrink in size, technologies involved in fabricating dynamic random-access memory (DRAM) has reached 20 nm, which necessitates higher requirements for manufacturing the DRAM. Moreover, in fabricating DRAM arrays, due to continuous reduction in size and development of the fabricating technology, insulating performance of insulating layers also needs continuous improvement.

In existing contact hole structures of capacitors, the contact holes are filled with a conductive medium, and silicon nitride acts as a spacer between two adjacent contact holes. To reduce parasitic capacitance between the conductive medium, it is often necessary to increase the silicon nitride's thickness, resulting in a reduction the contact holes' sizes and affecting conductivity between the capacitor and an active area.

Therefore, increasing the resistance between the contacts of the capacitor nodes and reducing the parasitic capacitance generated between the dielectrics while maintaining the conductivity between the capacitor and the active area is an urgent problem to be solved.

### SUMMARY

The invention provides a semiconductor structure and a fabrication method for same, so as to address issues of increasing the resistance between the contacts of the capacitor nodes and reducing the parasitic capacitance generated between the dielectrics while maintaining the conductivity between the capacitor and the active area.

According to a first aspect, the invention provides a semiconductor structure, comprising: a substrate; a plurality of word-line structures, wherein the plurality of word-line structures extend along a first direction on the substrate and are arranged at intervals along a second direction, and the second direction is perpendicular to the first direction; a plurality of spacer structures, wherein the plurality of spacer structures are disposed above the plurality of word-line structures, at least one of the plurality of spacer structures comprises a first spacer layer and an air gap, the first spacer layer is disposed at a bottom portion of the spacer structures, and the air gap is disposed on the first spacer layer, and the air gap is located between the plurality of first spacer layers along the second direction; and a plurality of contact plugs, wherein the plurality of contact plugs are disposed between the plurality of spacer structures.

According to a second aspect, the invention provides a method of fabricating a semiconductor structure, comprising: providing a substrate, wherein the substrate is formed with a plurality of word-line structures extending along a first direction and arranged at intervals along a second direction, wherein the second direction is perpendicular to the first direction; forming a plurality of spacer structures above the plurality of word-line structures, wherein at least one of the plurality of spacer structures comprises a first spacer layer and an air gap, the first spacer layer is disposed at a bottom portion of the spacer structures, and the air gap is disposed on the first spacer layer, and the air gap is located between the plurality of first spacer layers along the second direction; and forming a plurality of contact plugs between the plurality of spacer structures.

### BRIEF DESCRIPTION OF DRAWINGS

To detailly explain the technical schemes of the embodiments or existing techniques, drawings that are used to illustrate the embodiments or existing techniques are provided. Obviously, the illustrated embodiments are just a part of those of the invention. A person having ordinary skill in the art can obtain other drawings without labor for inventiveness.

FIG. 1 is a schematic diagram of a semiconductor structure in the prior art.

FIG. 2 is a flowchart of a method of fabricating a semiconductor structure, according to some embodiments of the invention.

FIG. 3 is a flowchart of forming a spacer structure in a method for fabricating a semiconductor structure, according to some embodiments of the invention.

FIGS. 4-19 are schematic diagrams showing steps of a method for fabricating a semiconductor structure, according to some embodiments of the invention.

FIGS. 20-28 are schematic diagrams showing steps forming a step-shaped insulating structure in a method for fabricating a semiconductor structure, according to some embodiments of the invention.

The accompanying drawings described above have shown specific embodiments of the invention, which will be described in more detail below. These accompanying drawings and written descriptions are not intended to limit the scope of the concept of the invention in any way, but to explain the concept of the invention to those skilled in the art by reference to specific embodiments.

### DETAILED DESCRIPTION

Specific implementations of a semiconductor structure and a method of fabricating the semiconductor structure provided by some embodiments of the invention will be described in detail below with reference to the accompanying drawings.

In order to make the objects, technical solutions and advantages of the invention more clearly understood, exemplary embodiments will be further described in detail below with reference to specific embodiments and accompanying drawings. It should be understood, however, that these descriptions are exemplary only, and are not intended to limit the scope of the invention. Also, in the following description, descriptions of well-known structures and techniques are omitted to avoid unnecessarily obscuring the concepts of the invention.

Various structural and cross-sectional views of semiconductor structures according to some embodiments of the invention are shown in the drawings. Figures are not to scale, some details are exaggerated for clarity, and some details may have been omitted. Shapes of the various regions and layers shown in the figures, as well as their relative sizes and positional relationships are only exemplary, and in practice, there may be deviations due to manufacturing tolerances or technical limitations, and those skilled in the art should areas/layers with different shapes, sizes, relative positions can be additionally designed as desired.

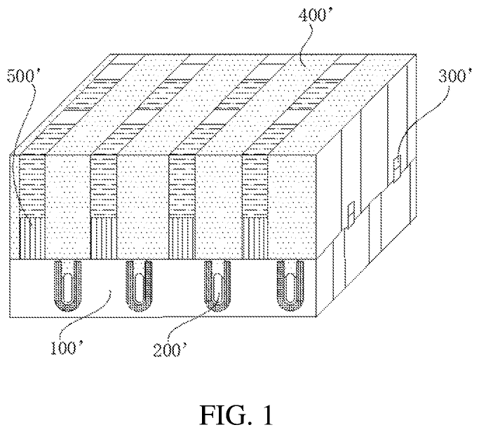

Referring to FIG. 1, which is a structural schematic diagram of a semiconductor structure in the prior art, comprising a substrate 100′, a plurality of word-line structures 200′ extending along a first direction and spaced apart along a second direction, a plurality of bit-line structures 300′ extending along the second direction and spaced along the first direction. Herein, in a cross section parallel to the second direction, a capacitor contact hole is formed between two adjacent word-line structures 200′, which is spaced apart by the spacer structures 400′ disposed on the substrate 100′. The capacitor contact hole is filled with a contact plug 500′. In order to reduce a parasitic capacitance generated between the contact plugs 500′, a thickness of the spacer structure 400′ needs to be controlled, resulting in a size of the capacitor contact hole not being able to be enlarged and a conductivity being affected.

Referring to FIG. 19, the X direction in the figure is the first direction, and the Y direction in the figure is the second direction. Some embodiments of the invention provide a semiconductor structure comprising a substrate 100, a plurality of word-line structures 200, a plurality of spacer structures 400, and a plurality of contact plugs 500.

The substrate 100 may also include a plurality of word-line structures 200. It can be understood that a plurality of shallow trench isolation structures, a plurality of doped regions, or other well-known semiconductor structures, etc. may also be formed in the substrate 100, which are not limited in these embodiments. In addition, the structures not designed with reference numbers in the figures may be known semiconductor structures and the like (for example, related structures required for forming capacitor contact holes), which are not limited in these embodiments;

The plurality of word-line structures 200 extend along the first direction on the substrate 100 and are arranged at intervals along the second direction, and the second direction is perpendicular to the first direction;

The plurality of spacer structures 400 are disposed above the word-line structures 200. Specifically, in the cross section along the second direction, the word-line structures 200 are located in the substrate 100, and the spacer structures 400 are disposed above the word-line structures 200. At least one of the spacer structures 400 comprises a first spacer layer 402 and an air gap 401, the first spacer layer 402 is disposed at a bottom portion of the spacer structures 400, and the air gap 401 is disposed above the first spacer layer 402, the air gap 401 is located between the first spacer layers 402 along the second direction. It should be noted that the spacer structures 400 comprise silicon nitride, and the first spacer layer comprises silicon oxide. Herein, the first spacer layer 402 is located at the bottom portion of the spacer structures, a nitride-oxide-nitride (NON) structure is formed at the bottom portion, and the air gap 401 is above the first spacer layer 402; and

The plurality of contact plugs 500 are disposed between the spacer structures 400.

It should be noted that, since air has good insulating properties and a relatively small dielectric coefficient, the coupling effect between the contact plugs 500 can be reduced by forming the air gap 401 in the upper portion of the spacer structures 400 between the capacitor contact holes. At the same time, the first spacer layer 402 is disposed in the lower portion of the spacer structures 400, and the material of the first spacer layer 402 is different from that of the spacer structure 400. Therefore, an alternative structure form with different materials can be formed, thereby further improving the resistance between the capacitor contact holes.

In semiconductor structures provided by the embodiments of the invention, at least one of the spacer structures 400 is provided with a first spacer layer 402 and an air gap 401, so as to improve the resistance between the capacitor contact holes, increase the insulating performance between the capacitor contact holes, and reduce generation of the parasitic capacitance and increase a spacing resistance between the capacitor contact holes, which helps to reduce a spacing size of the capacitor contact holes, expand a size of the capacitor contact holes, and improve the conduction effects between the capacitor and the active area.

The substrate is provided with a plurality of trenches extending along the first direction, and at least one of the word-line structures 200 comprises a gate dielectric layer 210 and a gate electrode 220. The gate dielectric layer 210 is located on sidewalls of the trench in the substrate 100, and the gate electrode 220 is located in the gate dielectric layer 210. The first spacer layer 402 is located above the gate dielectric layer 210, and the first spacer layer 402 is located on both sides of the gate electrode 220 along the second direction.

In one embodiment, there are at least two air gaps 401 arranged at intervals along the second direction. Meanwhile, there are at least two first spacer layers 402 that are arranged at intervals along the second direction. The at least two air gaps 401 are located between the two first spacer layers 402 along the second direction.

In one embodiment, the number of air gaps 401 is multiple, and they are arranged at intervals along the second direction. Specifically, there may be a plurality of air gaps 401 in the interior of the spacer structures 400, and the plurality of air gaps 401 are arranged at intervals along the second direction to further increase the resistance between the capacitor contact holes.

At the same time, the number of the first spacer layers 402 is multiple, and they are arranged at intervals along the second direction. That is, there may be a plurality of the first spacer layers 402 inside the bottom portion of the spacer structures 400, and the plurality of first spacer layers 402 are arranged at intervals along the second direction to increase the resistance between the capacitor contact holes.

In one embodiment, bit-line structures 300 are further provided, and the bit-line structures 300 extend along the second direction on the substrate 100 and are arranged at intervals along the first direction. Herein, the substrate 100 is provided with the plurality of bit-line structures 300, and the bit-line structures 300 extend along the second direction and are arranged at intervals along the first direction. The bit-line structure 300 and the spacer structure 400 are arranged to intersect with each, so that the capacitor contact holes are formed between the bit-line structures 300 and the spacer structures 400.

At least one of the bit-line structures 300 comprises a bit-line conducting layer and a bit-line insulating layer. Herein, the bit-line conducting layer may comprise a non-metal conducting layer and a metal layer. The non-metal conductive layer may comprise polysilicon, amorphous silicon or other non-metal conductive materials comprising or not comprising silicon. The metal layer may comprise aluminum, tungsten, copper, aluminum alloy or other suitable low-resistance metal conductive materials. The bit-line insulating layer may comprise, but not limited to, silicon nitride, silicon oxynitride, silicon nitride carbide or other suitable insulating materials.

In one embodiment, a surface of the first spacer layer 402 is lower than a surface of the bit-line structure 300. Specifically, an upper surface of the first spacer layer 402 in the spacer structures 400 is lower than an upper surface of the bit-line structures 300.

In one embodiment, at least one of the contact plugs 500 comprises a first conductive structure 510 and a second conductive structure 520 sequentially disposed on the substrate 100. It should be noted that the materials of the first conductive structure 510 and the second conductive structure 520 are different. Herein, the material of the first conductive structure 510 can be polysilicon but is not limited thereto. The polysilicon has good adhesion to the active area and can effectively connect the active area and the second conductive structure 520. The material of the second conductive structure 520 can be metal tungsten and/or metal titanium but is not limited thereto.

In one embodiment, the surface of the first conductive structure 510 is level with the surface of the first spacer layer 402, and the surface of the second conductive structure 520 is level with the surface of the air gap 401.

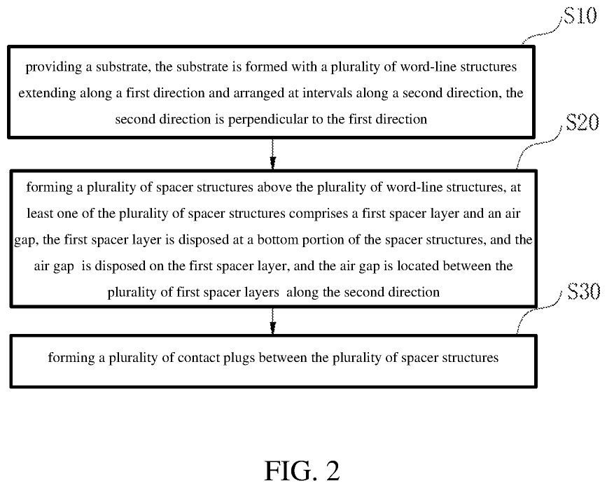

Based on the same concepts, embodiments of the invention also provide a method of fabricating a semiconductor structure. Referring to FIG. 2, the method of fabricating the semiconductor structure specifically comprises:

Step S10: providing a substrate 100, wherein the substrate 100 is formed with a plurality of word-line structures 200 extending along a first direction and arranged at intervals along a second direction, wherein the second direction is perpendicular to the first direction;

Step S20: forming a plurality of spacer structures 400 above the plurality of word-line structures 200, wherein at least one of the plurality of spacer structures 400 comprises a first spacer layer 402 and an air gap 401, the first spacer layer 402 is disposed at a bottom portion of the spacer structures 400, and the air gap 401 is disposed on the first spacer layer 402, and the air gap 401 is located between the plurality of first spacer layers 402 along the second direction; and

Step S30: forming a plurality of contact plugs 500 between the plurality of spacer structures 400.

In this embodiment, in the method of fabricating the semiconductor structure, the spacer structures 400 are formed above the word-line structures 200 on the substrate 100. Herein, at least one of the spacer structures 400 is provided with a first spacer layer 402 and an air gap 401, so as to improve the resistance between the capacitor contact holes, increase the insulating performance between the capacitor contact holes, and reduce generation of the parasitic capacitance and increase a spacing resistance between the capacitor contact holes, which helps to reduce a spacing size of the capacitor contact holes, expand a size of the capacitor contact holes, and improve the conduction effects between the capacitor and the active area.

In this embodiment, the substrate 100 may be a silicon substrate, an epitaxial silicon substrate, a silicon germanium substrate, a silicon carbide substrate or a silicon-on-insulator substrate but is not limited thereto.

Herein, the spacer structure 400 may be made of silicon nitride but is not limited to, and the first spacer layer 402 may be made of silicon oxide but is not limited to.

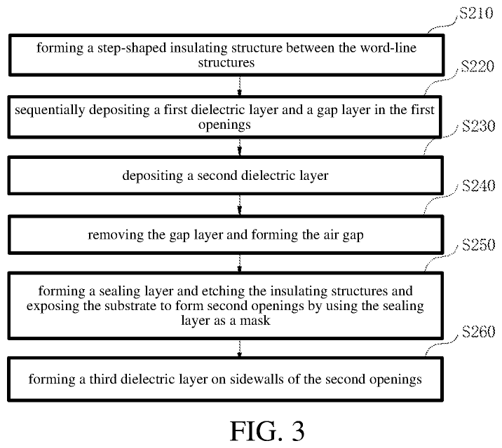

In one embodiment, in step S20, as shown in FIG. 3, forming the plurality of spacer structures 400 above the plurality of word-line structures 200 comprises Step S210, S220, S230, S240, S250 and S260.

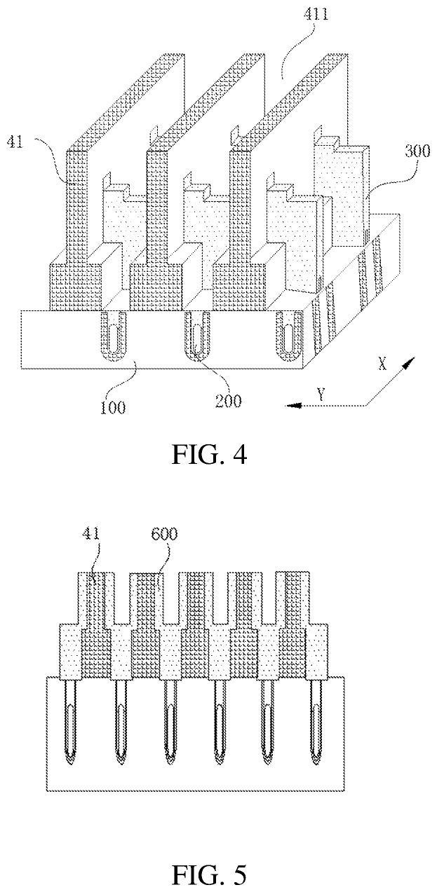

Step S210: as shown in FIG. 4, a plurality of step-shaped insulating structures 41 between the plurality of word-line structures 200 are formed, and a plurality of first openings 411 between the plurality of insulating structures 41 are formed. At least one of the plurality of first openings 411 comprises an upper part and a lower part. A width of the upper part is less than a width of the lower part. Herein, a material of the step-shaped insulating structures may be silicon oxide but is not limited to.

Step S220: sequentially depositing a first dielectric layer 600 and a gap layer 700 in the plurality of first openings 411, wherein the first dielectric layer 600 fills the lower part of the plurality of first openings 411 and covers sidewalls of the upper part of the plurality of first openings 411, and the gap layer 700 covers sidewalls of the first dielectric layer 600 on the sidewalls of the upper part of the plurality of first openings 411. A material of the first dielectric layer 600 may be silicon nitride but is not limited thereto, and a material of the gap layer may be carbon but is not limited thereto.

Step 230: A second dielectric layer 800 is deposited. The second dielectric layer 800 fills the upper part of the plurality of first openings 411, wherein the second dielectric layer 800 may use a material the same as that of the first dielectric layer 600, and may use a material not limited to the silicon nitride.

S240: The gap layer 700 is removed and the air gap 401 is formed.

S250: A sealing layer 900 is formed. The sealing layer 900 covers an upper portion of the air gap 401 and the second dielectric layer 800 to seal the air gap 401. Etching the plurality of insulating structures and exposing the substrate to form a plurality of second openings 412 by using the sealing layer as a mask, and forming the first spacer layer on bottom sidewalls of the plurality of second openings 412. The sealing layer 900, first dielectric layer 600 and second dielectric layer 800 are made of silicon nitride, but not limited thereto.

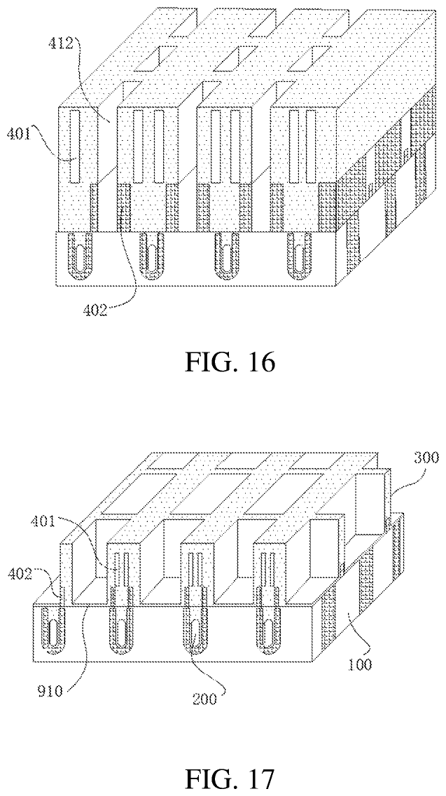

Step 260: as shown in FIG. 16 and FIG. 17, a third dielectric layer on sidewalls of the plurality of second openings 412 is formed. After etching the plurality of insulating structures 41 and exposing the substrate 100 to form a plurality of second openings 412, the third dielectric layer 910 is formed on sidewalls of the plurality of second openings 412. The third dielectric layer 910 and second dielectric layer 800 are made of silicon nitride, but not limited thereto.

In one embodiment, the Step 220 of sequentially depositing the first dielectric layer 600 and the gap layer 700 in the plurality of first openings 411 comprises the following steps:

forming the first dielectric layer 600 filling the lower part of the plurality of first openings, sidewalls of the upper part of the plurality of first openings, and a top surface of the plurality of insulating structures; and

etching and removing the first dielectric layer 600 on the top surface of the plurality of insulating structures 41.

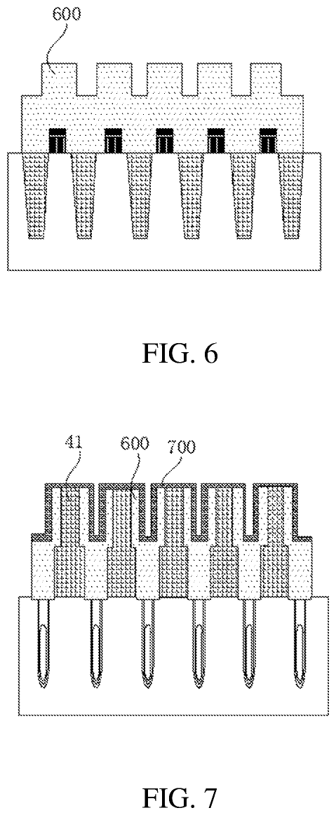

As shown in FIGS. 5-6, FIG. 5 is a cross section along a direction parallel to the word-line structures 200, and FIG. 6 is a cross section along a direction parallel to the bit-line structure 300. Specifically, a deposition method can be used to form the above-mentioned first dielectric layer 600. The deposition method may comprise atmospheric pressure chemical vapor deposition (APCVD), low pressure chemical vapor deposition (LPCVD), plasma-enhanced chemical vapor deposition (PECVD), high-density plasma chemical vapor deposition (HDP-CVD), radical-enhanced chemical vapor deposition (RECVD), or atomic layer deposition (ALD).

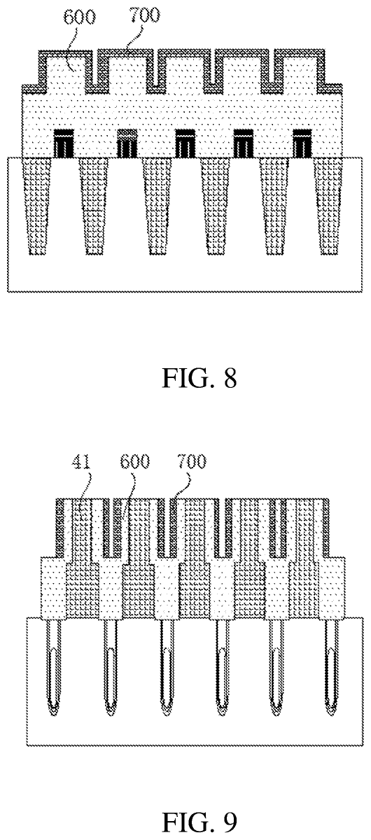

As shown in FIG. 7 and FIG. 8, FIG. 7 illustrates a cross section along a direction parallel to the word-line structures 200, and FIG. 8 illustrates a cross section along a direction parallel to the bit-line structures 300. The gap layer 700 is deposited to cover the top surface of the plurality of insulating structures 41 and the first dielectric layer 600, and the bottom and the sidewalls of the upper part of the plurality of first openings 700.

As shown in FIG. 7 and FIG. 8, FIG. 7 is a cross-sectional view in a direction parallel to the word-line structure 200, and FIG. 8 is a cross-sectional view in a direction parallel to the bit-line structure 300. A gap layer 700 is deposited covering the top surface of the insulating structure 41 and the first dielectric layer 600, and the bottom and sidewalls of the upper portion of the first opening 411.

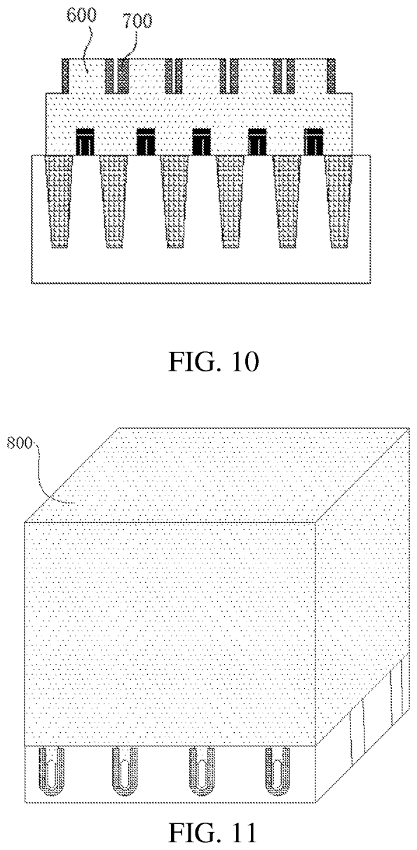

As shown in FIG. 9 and FIG. 10, FIG. 9 is a cross section along a direction parallel to the word-line structures 200, and FIG. 10 is a cross section along a direction parallel to the bit-line structures 300. By etching a portion of the gap layer 700, the gap layer 700 (comprising the gap layer 700 on the insulating structures 41 and the top portion and the bottom of the upper part of the first dielectric layer 600) located on the sidewalls of the first dielectric layer 600 on upper sidewalls of the plurality of first openings 411 are retained.

In one embodiment, as shown in FIG. 11, the step S230 of depositing the second dielectric layer 800 comprises: forming the second dielectric layer 800 to fill the upper part of the plurality of first openings 411, and covering the insulating structures 41, the first dielectric layer 600, and a top surface of the gap layer 700. A method such as ALD or CVD may be used to form the second dielectric layer 800.

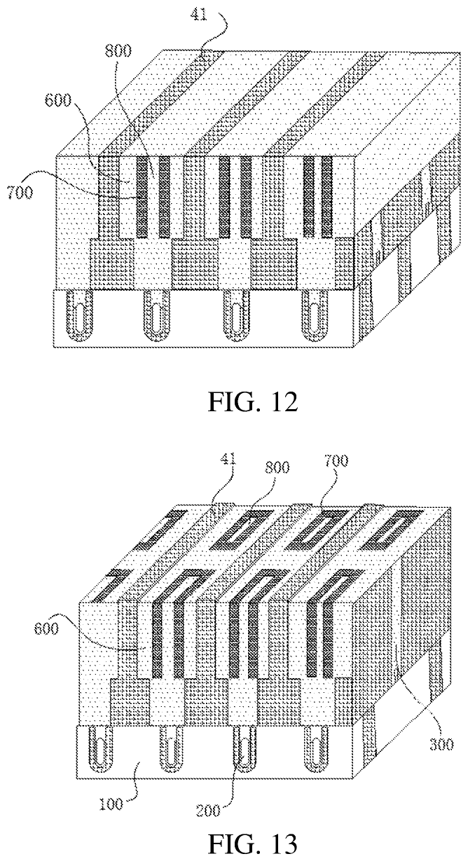

As shown in FIG. 12, the plurality of insulating structures 41 are exposed through a planarization process. Specially, the planarization process may be a chemical mechanical planarization process, and it should be noted that an etch-back process may also be used to expose the insulating structure 41.

As shown in FIG. 13, the top surface of the gap layer 700 is posed by etching the first dielectric layer 600 and the second dielectric layer 800 between the insulating structures 41.

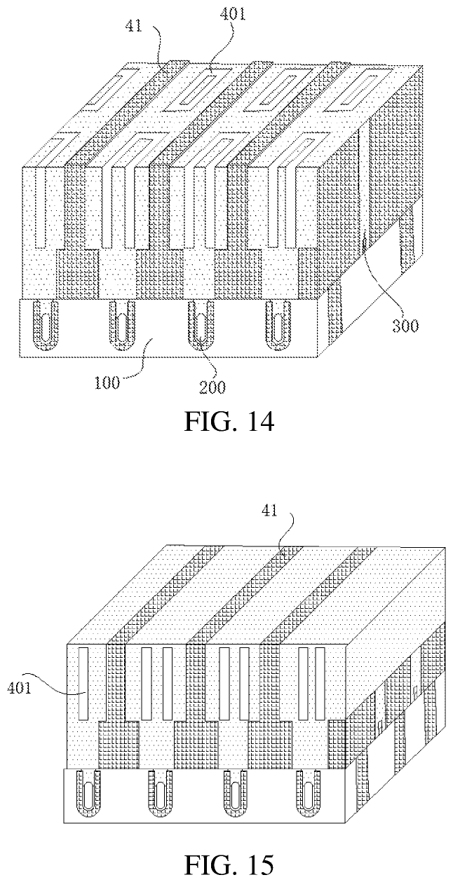

In one embodiment, as shown in FIG. 14, the gap layer 700 is removed by an etching process. Specifically, the air gap 401 is formed by removing the gap layer 700 through an etching process, and the size of the air gap 401 is approximately equal to the size of the gap layer 700.

In one embodiment, as illustrated in FIG. 15, forming the sealing layer 900 comprises: forming the sealing layer 900 over the air gap 401. A height of the sealing layer 900 is greater than the top surface of the insulating structure 41, and the sealing layer 900 may also be formed by atomic layer deposition or chemical vapor deposition.

The sealing layer 900 is removed to expose the top surface of the insulating structure 41 through a planarization process.

In one of the embodiments, the operations of forming the third dielectric layer 910 on the sidewalls of the second opening 412 comprises:

As shown in FIG. 16 and FIG. 17, a third dielectric layer 910 covering the sealing layer 900 and the bottom and side walls of the second opening 412 is formed, and the third dielectric layer 910 can also be formed by atomic layer deposition or chemical vapor deposition.

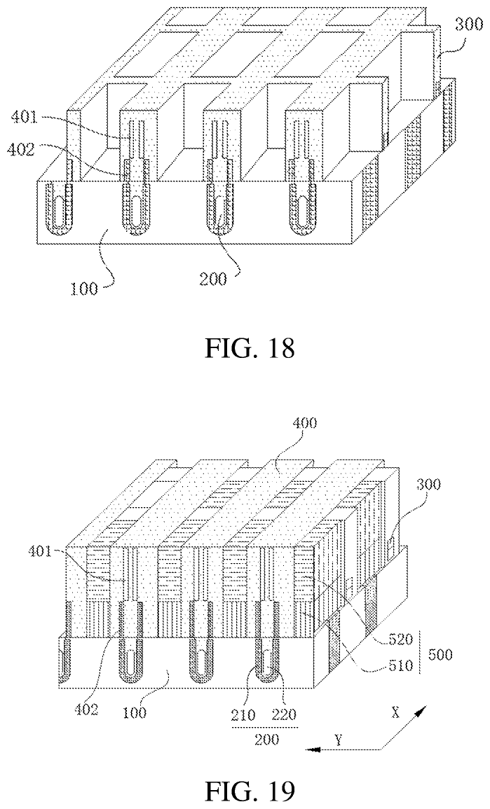

As shown in FIG. 18, the top portion of the sealing layer 900 and the third dielectric layer 910 on the bottom wall of the second opening 412 are removed by etching.

In one embodiment, as shown in FIG. 19, forming the contact plugs 500 between the spacer structures 400 comprising: sequentially forming a first conductive structure 510 and a second conductive structure 520 on the substrate 100, wherein the material of the first conductive structure the structure 510 comprises polysilicon but is not limited thereto, and the material of the second conductive structure 520 comprises metal tungsten and/or metal titanium but is not limited thereto.

In one embodiment, forming the plurality of step-shaped insulating structures 41 between the plurality of word-line structures 200 comprises:

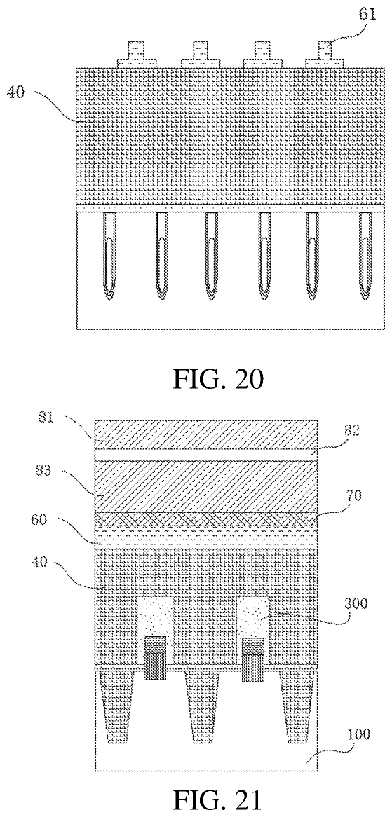

As shown in FIG. 20, a fourth dielectric layer 40 is deposited on a surface of the substrate 100. The fourth dielectric layer 40 can be made of silicon oxide. Similarly, a method such as atomic layer deposition or chemical vapor deposition can be used to form the fourth dielectric layer 40.

A plurality of step-shaped first masks 61 are formed on a surface of the fourth dielectric layer 40, wherein the plurality of first masks 61 extend along the first direction and are arranged at intervals along the second direction, and the plurality of first masks 61 are between the plurality of word-line structures 41.

As shown in FIG. 4, the fourth dielectric layer 40 is etched to expose the substrate 100 and form the plurality of step-shaped insulating structures 41.

The bit-line structures 300 in the substrate 100 comprises a conductive layer and an insulating layer disposed outside the conductive layer for wrapping the conductive layer, and the material of the insulating layer may comprise silicon nitride. Specifically, in this embodiment, since the materials of the fourth dielectric layer 40 and the insulating layer of the bit-line structures 300 are different, etching rates of these two layers are also different. In one embodiment, the etchant has different etching rates against the materials of the fourth dielectric layer 40 and the insulating layer. For example, an etching rate of the etchant used in the etching for the material of the fourth dielectric layer 40 is greater than an etching rate of the etchant used in the etching for the material of the insulating layer. Therefore, when the fourth dielectric layer 40 is etched and the substrate 100 is exposed, only a small portion of the insulating layer is etched. That is, the fourth dielectric layer 40 is etched on the premise that the bit-line structures 300 are retained.

In one embodiment, forming the plurality of step-shaped first masks 61 on the surface of the fourth dielectric layer 40 comprises:

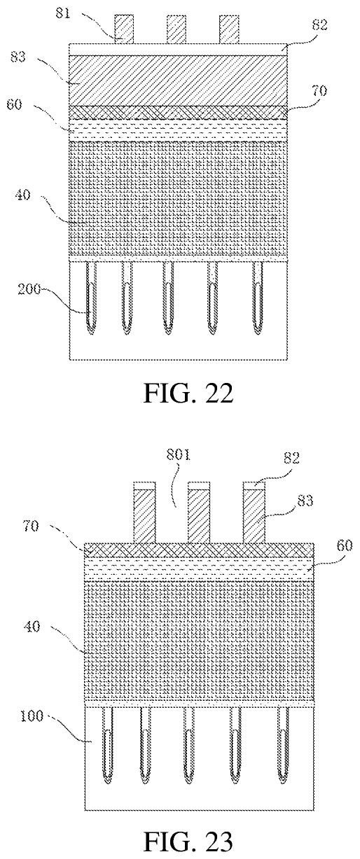

As shown in FIG. 21 and FIG. 22, FIG. 21 is a cross section along a direction parallel to the word-line structures 200, and FIG. 22 is a cross section along a direction parallel to the bit-line structures 300. A first mask layer 60, a second mask layer 70, a sacrificial layer 83 and an anti-reflection coating 82 are sequentially deposited on the surface of the fifth dielectric layer 40. The material of the first mask layer 60 comprises carbon but is not limited thereto. Specifically, the first mask layer 60 can also be formed by atomic layer deposition or chemical vapor deposition. The material of the second mask layer 70 comprises silicon oxynitride but is not limited thereto, and the material of the sacrificial layer 83 comprises spin on carbon (SOC) but is not limited thereto.

As shown in FIG. 23, a plurality of third openings 801 are formed in the anti-reflection coating 82 and the sacrificial layer 83 based on the patterned photoresist 81.

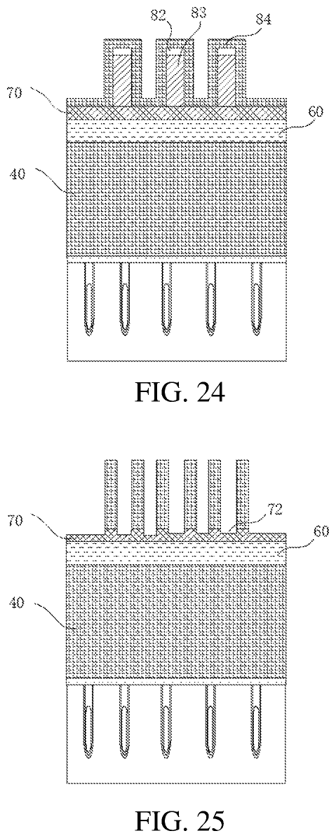

As shown in FIG. 24, a fifth dielectric layer 84 covering the anti-reflection coating 82 and the bottom and sidewalls of the third openings 801 is formed, wherein the material of the fifth dielectric layer 84 comprises silicon oxide but is not limited thereto. Specifically, the fifth dielectric layer 84 may also be formed by atomic layer deposition or chemical vapor deposition.

As shown in FIG. 25, after removing the fifth dielectric layer 84 at the bottom portion of the third opening 801, the anti-reflection coating 82 and the fifth dielectric layer 84 on the top surface of the sacrificial layer 83, the sacrificial layer 83 is removed to form a third mask. The second mask layer 70 is etched based on the third mask to form the first trenches 72.

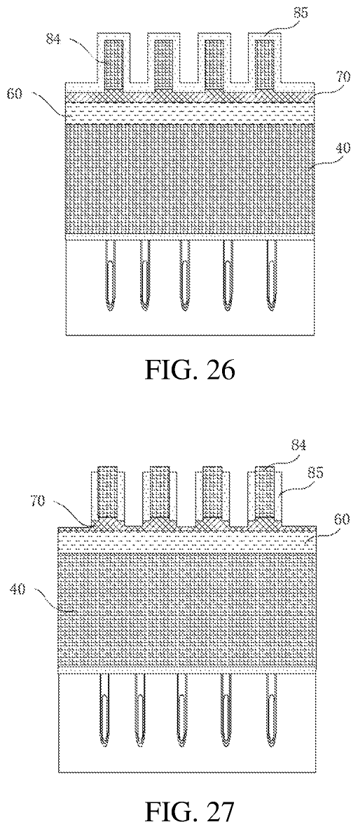

As shown in FIG. 26, a sixth dielectric layer 85 covering the top surface and sidewalls of the third mask and the first trench 72 is formed. The material of the sixth dielectric layer 85 comprises silicon nitride but is not limited thereto. The sixth dielectric layer 85 can be formed by a method such as atomic layer deposition, chemical vapor atomic layer deposition or chemical vapor deposition.

The top surface of the third mask and the sixth dielectric layer 85 of the first trench 72 are removed, and the sixth dielectric layer 85 of the sidewalls of the third mask is retained. The third mask and the sixth dielectric layer 85 form a fourth mask.

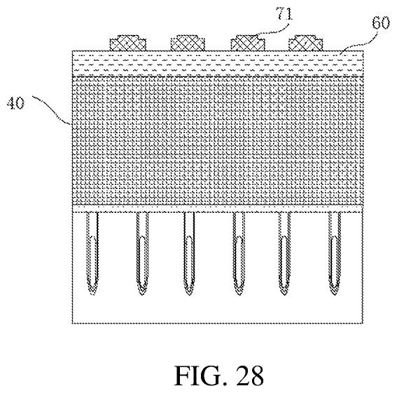

As shown in FIG. 27 and FIG. 28, the second mask layer 70 is etched to form a plurality of step-shaped second masks 71 on the surface of the first mask layer 60. Then, the fourth mask is removed. The second masks 71 extends along the first direction and are arranged at intervals in the second direction, and the second masks 71 are located between two adjacent word-line structures 200.

As shown in FIG. 20, the first mask layer 60 is etched based on the above-mentioned second masks 71 to form a step-shaped first masks.

In this embodiment, the step-shaped first masks 61 are formed by etching the step-shaped second masks 71, and the height of the upper part and the lower part of the formed second masks 71 can be different based on the etching ratios and can be selected according to actual needs.

In one embodiment, an automatic alignment double-exposure process is used to form the fifth dielectric layer 84 covering the anti-reflection coating 82 and the bottom and sidewalls of the third opening 801.

At the same time, an automatic alignment double-exposure process can also be used to form a sixth dielectric layer 85 covering the top surface and sidewalls of the third masks and the first trenches 72.

In the above embodiment, dry etching or wet etching process may be used. Those skilled in the art can select the specific process and parameters with reference to the prior art, which will not be repeated here.

Some embodiments of the invention provides a semiconductor structure, comprising: a substrate 100; a plurality of word-line structures 200, wherein the plurality of word-line structures 200 extend along a first direction on the substrate and are arranged at intervals along a second direction, and the second direction is perpendicular to the first direction; a plurality of spacer structures 400, wherein the plurality of spacer structures 400 are disposed above the plurality of word-line structures 200, at least one of the plurality of spacer structures 200 comprises a first spacer layer 402 and an air gap 401, the first spacer layer 402 is disposed at a bottom portion of the spacer structures 400, and the air gap 401 is disposed on the first spacer layer 402, and the air gap 401 is located between the plurality of first spacer layers 402 along the second direction; and a plurality of contact plugs 500, wherein the plurality of contact plugs 500 are disposed between the plurality of spacer structures 400. Since at least one of the spacer structures 400 is provided with a first spacer layer 402 and an air gap 401, thereby improving the resistance between the capacitor contact holes, increasing the insulating performance between the capacitor contact holes, and reducing the generation of parasitic capacitance. Meanwhile, a spacing size of the capacitor contact holes is increased, a size of the capacitor contact holes is expanded, and conduction effects between the capacitor and the active area are improved.

Some embodiments of the invention provide a method of fabricating a semiconductor structure, comprising: providing a substrate 100, wherein the substrate 100 is formed with a plurality of word-line structures 200 extending along a first direction and arranged at intervals along a second direction, wherein the second direction is perpendicular to the first direction; forming a plurality of spacer structures 400 above the plurality of word-line structures 200, wherein at least one of the plurality of spacer structures 200 comprises a first spacer layer 402 and an air gap 401, the first spacer layer 402 is disposed at a bottom portion of the spacer structures 400, and the air gap 401 is disposed on the first spacer layer 400, and the air gap 401 is located between the plurality of first spacer layers 402 along the second direction; and forming a plurality of contact plugs 500 between the plurality of spacer structures 400. Since at least one of the spacer structures 400 is provided with a first spacer layer 402 and an air gap 401, a resistance between the capacitor contact holes is increased by the first spacer layer 402 and the air gap 401, thereby increasing the insulating performance between the capacitor contact holes and reducing the generation of parasitic capacitance. At the same time, increases of the resistance between the capacitor contact holes help to increase a spacing size of the capacitor contact holes, expand a size of the capacitor contact holes, and improve conduction effects between the capacitor and the active area.

In the above description, technical details such as patterning and etching of each layer are not described in detail. However, those skilled in the art should understand that layers, regions, etc. of desired shapes can be formed by various means in the prior art. In addition, in order to form the same structure, those skilled in the art can also design methods that are not exactly the same as those described above. Although various embodiments have been described above separately, it does not imply that the advantageous features of these embodiments cannot be used in combination.

The specific embodiments described above further describe the purpose, technical solutions and beneficial effects of the invention in detail. It should be understood that the above are only specific embodiments of the invention and are not intended to limit the invention. Any modification, equivalent replacement, improvement, etc. made within the spirit and principle of the invention shall be included within the protection scope of the invention.

The above are only the preferred embodiments of the invention. It should be pointed out that for those skilled in the art, without departing from the principles of the invention, several improvements and modifications can also be made, and these improvements and modifications should also be regarded as the protection scope of the invention.

It should be understood that the above-mentioned specific embodiments of the invention are only used to illustrate or explain the principles of the invention, but not to limit the invention. Therefore, any modifications, equivalent replacements, improvements, etc. made without departing from the spirit and scope of the invention shall be included within the protection scope of the invention. Furthermore, the appended claims of the invention are intended to cover all changes and modifications that fall within the scope and boundaries of the appended claims, or the equivalents of such scope and boundaries.

What is claimed is:

1. A semiconductor structure, comprising:
a substrate;
a plurality of word-line structures, extending along a first direction on the substrate and arranged at intervals along a second direction perpendicular to the first direction;
a plurality of spacer structures, disposed above the plurality of word-line structures, wherein at least one of the plurality of spacer structures comprises a first spacer layer and an air gap, the first spacer layer is disposed at a bottom portion of the plurality of spacer structures, the air gap is disposed on the first spacer layer, and the air gap is located between the plurality of first spacer layers along the second direction; and
a plurality of contact plugs, disposed between the plurality of spacer structures.

2. The semiconductor structure of claim 1, wherein:
at least one of the plurality of word-line structures comprises a gate dielectric layer and a gate electrode, the gate dielectric layer is located on sidewalls of a trench in the substrate, and the gate electrode is located in the gate dielectric layer; and
the first spacer layer is located above the gate dielectric layer, and the first spacer layer is located on both sides of the gate electrode along the second direction.

3. The semiconductor structure of claim 1, wherein:
at least one of the plurality of spacer structures comprises at least two of the air gaps arranged at intervals along the second direction; and
at least one of the plurality of spacer structures comprises at least two first spacer layers arranged at intervals along the second direction.

4. The semiconductor structure of claim 3, wherein the at least two air gaps are located between the at least two first spacer layers along the second direction.

5. The semiconductor structure of claim 4, wherein the plurality of spacer structures comprise silicon nitride, the first spacer layer comprises silicon oxide, and the bottom portion of the plurality of spacer structures forms a nitride-oxide-nitride structure.

6. The semiconductor structure of claim 1, wherein the plurality of contact plugs comprise a first conductive structure and a second conductive structure sequentially disposed on the substrate.

7. The semiconductor structure of claim 6, wherein the first conductive structure comprises polysilicon, and the second conductive structure comprises metal tungsten and/or metal titanium.

8. The semiconductor structure of claim 6, wherein a surface of the first conductive structure is level with a surface of the first spacer layer, and a surface of the second conductive structure is level with a surface of the air gap.

9. The semiconductor structure of claim 1, further comprising:
a plurality of contact holes, wherein at least one of the plurality of contact holes is formed between two adjacent word-line structures of a plurality of word-line structures, and the air gap is formed between two adjacent capacitor contact holes of the plurality of contact holes.

10. A method of fabricating a semiconductor structure, comprising:
providing a substrate;
forming a plurality of word-line structures on the substrate, the plurality of word-line structures extending along a first direction and arranged at intervals along a second direction, wherein the second direction is perpendicular to the first direction;
forming a plurality of spacer structures above the plurality of word-line structures, wherein at least one of the plurality of spacer structures comprises a first spacer layer and an air gap, the first spacer layer is disposed at a bottom portion of the spacer structures, the air gap is disposed on the first spacer layer, and the air gap is located between the plurality of first spacer layers along the second direction; and
forming a plurality of contact plugs between the plurality of spacer structures.

11. The method of claim 10, wherein forming the plurality of spacer structures above the plurality of word-line structures comprises:
forming a plurality of step-shaped insulating structures between the plurality of word-line structures;
forming a plurality of first openings between the plurality of step-shaped insulating structures, wherein the plurality of first openings comprising an upper part and a lower part, and a width of the upper part of the plurality of first openings is less than a width of the lower part of the plurality of first openings;
sequentially depositing a first dielectric layer and a gap layer in the plurality of first openings, wherein the first dielectric layer fills the lower part of the plurality of first openings and covers sidewalls of the upper part of the plurality of first openings, and the gap layer covers sidewalls of the first dielectric layer on the sidewalls of the upper part of the plurality of first openings;
depositing a second dielectric layer, wherein the second dielectric layer fills the upper part of the plurality of first openings; and
removing the gap layer to form the air gap.

12. The method of claim 11, wherein after forming the air gap, the method further comprises:
forming a sealing layer, wherein the sealing layer covers an upper portion of the air gap and the second dielectric layer to seal the air gap;
etching the plurality of insulating structures to expose the substrate to form a plurality of second openings by using the sealing layer as a mask; and
forming the first spacer layer on bottom sidewalls of the plurality of second openings.

13. The method of claim 12, wherein after forming the first spacer layer, the method further comprises forming a third dielectric layer on sidewalls of the plurality of second openings.

14. The method of claim 11, wherein sequentially depositing the first dielectric layer and the gap layer in the plurality of first openings comprises:
forming the first dielectric layer filling the lower part of the plurality of first openings, sidewalls of the upper part of the plurality of first openings, and a top surface of the plurality of insulating structures;
etching the first dielectric layer on the top surface of the plurality of insulating structures;
depositing the gap layer that covers the top surface of the plurality of insulating structures and the first dielectric layer, and the bottom and the sidewalls of the upper part of the plurality of first openings; and
etching a portion of the gap layer, with the gap layer located on the sidewalls of the first dielectric layer on upper sidewalls of the plurality of first openings retained.

15. The method of claim 11, wherein depositing the second dielectric layer comprises:
forming the second dielectric layer that fills the upper part of the plurality of first openings and covers the insulating structures, the first dielectric layer, and a top surface of the gap layer;
exposing the plurality of insulating structures through a planarization process; and
exposing the top surface of the gap layer by etching the first dielectric layer and the second dielectric layer between the insulating structures.

16. The method of claim 11, wherein forming the plurality of step-shaped insulating structures between the plurality of word-line structures comprises:
depositing a fourth dielectric layer on a surface of the substrate;
forming a plurality of step-shaped first masks on a surface of the fourth dielectric layer, wherein the plurality of first masks extend along the first direction and are arranged at intervals along the second direction, and the plurality of first masks are between the plurality of word-line structures; and
etching the fourth dielectric layer to expose the substrate and form the plurality of step-shaped insulating structures.

17. The method of claim 16, wherein forming the plurality of step-shaped first masks on the surface of the fourth dielectric layer comprises:
forming a first mask layer on the surface of the fourth dielectric layer;
forming a plurality of step-shaped second masks on a surface of the first mask layer, wherein the plurality of second masks extend along the first direction and are arranged at intervals along the second direction, and the plurality of second masks are disposed between adjacent ones of the word-line structures; and
etching the first mask layer to form the plurality of step-shaped first masks.

18. The method of claim 17, wherein forming the plurality of step-shaped second masks on the surface of the first mask layer comprises:
sequentially forming a second mask layer, a sacrificial layer, and an anti-reflection coating on the surface of the first mask layer;
forming a plurality of third openings in the anti-reflection coating and the sacrificial layer based on a patterned photoresist;
forming a fifth dielectric layer covering the anti-reflection coating and a bottom portion and sidewalls of the plurality of third openings;
forming a plurality of third masks in response to removing the fifth dielectric layer at the bottom portion of the plurality of third openings, the anti-reflection coating on a top surface of the sacrificial layer, and the fifth dielectric layer on the top surface of the sacrificial layer;
forming a plurality of first trenches by etching the second mask layer based on the plurality of third masks;
forming a sixth dielectric layer covering a top surface and sidewalls of the plurality of third masks and the plurality of first trenches;
removing the sixth dielectric layer above the top surface of the plurality of third masks and the plurality of first trenches;
forming the sixth dielectric layer on the sidewalls of the plurality of third masks, wherein the plurality of third masks and the sixth dielectric layer form a fourth mask; and
etching the second mask layer to form the plurality of step-shaped second masks.

19. The method of claim 18, wherein:
an automatic alignment double-exposure process is used to form the fifth dielectric layer covering the anti-reflection coating and the bottom portion and the sidewalls of the plurality of third openings; and
the automatic alignment double-exposure process is used to form the sixth dielectric layer covering the top surface and the sidewalls of the plurality of third masks and the plurality of first trenches.
